(19) United States
(12) Patent Application Publication
(10) Pub. No.: US 2014/0042604 A1
(43) Pub. Date: Feb. 13, 2014

(54) THREE-DIMENSIONAL (3D) SEMICONDUCTOR PACKAGE

(71) Applicant: SAMSUNG ELECTRO-MECHANICS CO., LTD., Gyunggi-do (KR)

(72) Inventors: Hyung Jin Jeon, Gyunggi-do (KR); Jong Yun Lee, Gyunggi-do (KR); Kyoung Moo Harr, Gyunggi-do (KR)

(73) Assignee: SAMSUNG ELECTRO-MECHANICS CO., LTD., Gyunggi-do (KR)

(21) Appl. No.: 13/673,910

(22) Filed: Nov. 9, 2012

(30) Foreign Application Priority Data
Aug. 10, 2012 (KR) 10-2012-0087743

(51) Int. Cl. H01L 23/498

(52) U.S. Cl. CPC H01L 23/49827
USPC 257/676; 257/E23.067

(57) ABSTRACT

Disclosed herein is a three-dimensional (3D) semiconductor package. The 3D semiconductor package includes a printed circuit board, a main interposer that is formed on the printed circuit board, a semiconductor device that is formed on the main interposer, and a support interposer that is disposed on the same plane as a plane of the semiconductor device, or disposed between the main interposer and the semiconductor device. Here, each of the main interposer, the semiconductor device, and the support interposer may include a through-via formed based on a thickness direction of the printed circuit board.

### CROSS REFERENCE TO RELATED APPLICATION

This application claims the benefit of Korean Patent Application No. 10-2012-0087743, filed on Aug. 10, 2012, entitled “3D Semiconductor Package”, which is hereby incorporated by reference in its entirety into this application.

### BACKGROUND OF THE INVENTION

1. Technical Field

The present invention relates to a three-dimensional (3D) semiconductor package.

2. Description of the Related Art

At present, in the electronics industries, there are demands for inexpensively manufacturing lightweight, compact, high-speed, multi-function, and high-performance products with high reliability.

One of the important technologies that make this possible is a package technology with a variety of structures, including Patent Document 1, and a wafer level package technology among these may realize miniaturization, weight-lightening, and high-performance.

With the development of mobile devices, implementation of a system-on-chip (SoC) is required. In the implementation of SoC, there are limitations in implementing the technology so far due to technical limitations, high costs, and the like, and therefore 3D package technologies to replace these limitations have emerged.

However, in accordance with a variety of die sizes, a die-stacking process may be limited due to non-uniformity when stacking dies, and reliability of the process may weaken.

### PRIOR ART DOCUMENT

### Patent Document

(Patent Document 1) US 2008-0216314 A

### SUMMARY OF THE INVENTION

The present invention has been made in an effort to provide a 3D semiconductor package that may ensure stability in stacking between semiconductor devices with a variety of sizes when stacking the semiconductor devices.

According to an embodiment of the present invention, there is provided a three dimensional (3D) semiconductor package, including: a printed circuit board; a main interposer that is formed on the printed circuit board; a semiconductor device that is formed on the main interposer; and a support interposer that is disposed on the same plane as a plane of the semiconductor device or disposed between the main interposer and the semiconductor device, wherein each of the main interposer, semiconductor device, and the support interposer includes a through-via formed based on a thickness direction of the printed circuit board.

The 3D semiconductor package according to an embodiment of the present invention may further include an external connection terminal that is formed between the main interposer and the printed circuit board, and connected with the through-via to thereby be mutually electrically connected.

In the 3D semiconductor package according to an embodiment of the present invention, a plurality of semiconductor devices may be provided, and the 3D semiconductor package may further include an external connection terminal that is formed between the plurality of semiconductor devices and connected with the through-via, to thereby be mutually electrically connected.

The 3D semiconductor package according to an embodiment of the present invention may further include an external connection terminal that is formed between the semiconductor devices and the support interposer, and connected with the through-via, to thereby be mutually electrically connected.

In the 3D semiconductor package according to an embodiment of the present invention, the support interposer may include a circuit layer having a circuit pattern formed on an inner layer thereof.

In the 3D semiconductor package according to an embodiment of the present invention, the main interposer may include a circuit layer having a circuit pattern formed on an inner layer thereof.

In the 3D semiconductor package according to an embodiment of the present invention, the printed circuit board may include the semiconductor device built therein.

According to another embodiment of the present invention, there is provided a 3D semiconductor package including: a plurality of semiconductor devices; and a support interposer that is disposed on the same plane as a plane of the semiconductor device, or disposed between the plurality of semiconductor devices, wherein each of the semiconductor devices and the support interposer includes a through-via formed based on a thickness direction of the printed circuit board.

The 3D semiconductor package according to another embodiment of the present invention may further include an external connection terminal that is formed between the plurality of semiconductor devices, and connected with the through-via, to thereby be mutually electrically connected.

The 3D semiconductor package according to another embodiment of the present invention may further include an external connection terminal that is formed between the semiconductor devices and the support interposer, and connected with the through-via, to thereby be mutually electrically connected.

The 3D semiconductor package according to another embodiment of the present invention may further include a main interposer that is formed below the plurality of semiconductor devices, and a printed circuit board that is formed below the main interposer.

In the 3D semiconductor package according to another embodiment of the present invention, the main interposer may further include a through-via that is formed based on a thickness direction of the printed circuit board.

In the 3D semiconductor package according to another embodiment of the present invention, the printed circuit board may include a semiconductor device built therein.

### BRIEF DESCRIPTION OF THE DRAWINGS

The above and other objects, features, and advantages of the present invention will be more clearly understood from the following detailed description taken in conjunction with the accompanying drawings, in which:

FIG. 1 is a cross-sectional view showing a configuration of a 3D semiconductor package according to an embodiment of the present invention, in detail; and

FIG. 2 is a cross-sectional view showing a configuration of a 3D semiconductor package according to another embodiment of the present invention, in detail.

### DESCRIPTION OF THE PREFERRED EMBODIMENTS

The objects, features, and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side”, and the like are used to differentiate a certain component from other components, but the configuration of such components should not be construed to be limited by the terms.

Hereinafter, preferred embodiments of the present invention will be described in detail with reference to the attached drawings.

A three-dimensional (3D) semiconductor package disclosed in embodiments of the present invention will be defined as a substrate in which semiconductor devices such as integrated circuits (IC) semiconductor devices, integrated passive devices (IPD), components, micro electro mechanical system (MEMS) devices, or the like are connected through a through-via to be stacked. For this, the through-via is formed in each configuration.

### 3D Semiconductor Package

### First Embodiment

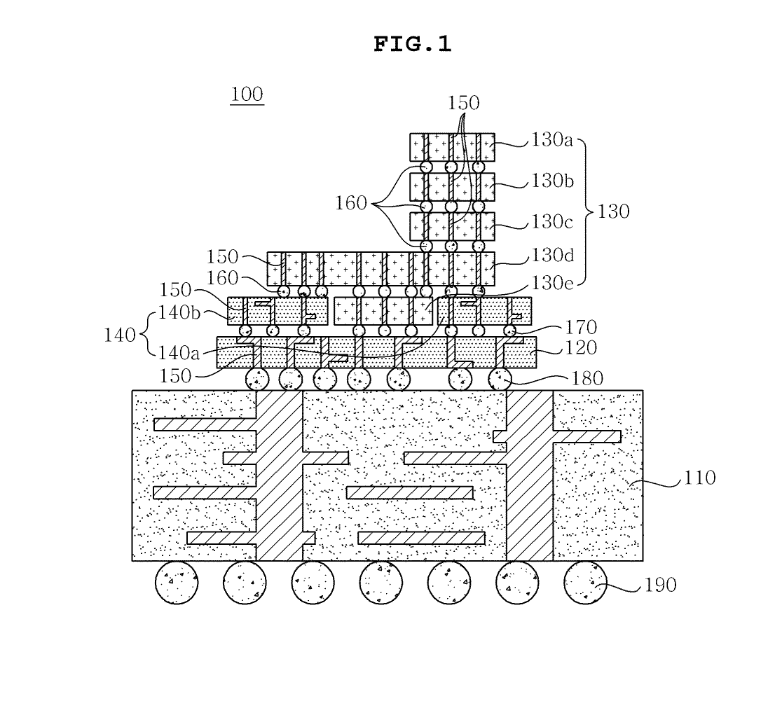

FIG. 1 is a cross-sectional view showing a configuration of a 3D semiconductor package according to an embodiment of the present invention, in detail, and a case in which a support interposer is formed between a main interposer and a semiconductor device will be described.

As shown in FIG. 1, the 3D semiconductor package 100 may include a printed circuit board 110, a main interposer 120, support interposers 140, 140a, and 140b (hereinafter, the reference numerals will be referred to as “140”), and semiconductor devices 130, 130a, 130b, 130c, 130d, and 130e (hereinafter, the reference numerals will be referred to as “130”).

As shown in FIG. 1, the main interposer 120 may be formed on the printed circuit board 110.

In this instance, the printed circuit board 110 may be a typical insulation layer applied as a core substrate in the printed circuit board fields, or a printed circuit board in which a circuit of one layer or more is formed on the insulation layer.

As the insulation layer, a resin insulation layer may be used. As the resin insulation layer, thermosetting resin such as epoxy resin, thermoplastic resin such as polyimide, or resin in which the above-described resins are impregnated with a reinforcement such as a glass fabric or an inorganic filler, for example, a prepreg may be used, or thermosetting resin or/and photocurable resin may be used, but the invention is not particularly limited thereto.

In addition, as shown in FIG. 1, the printed circuit board 110 may include an external connection terminal 190 formed in a lower portion thereof.

In addition, although not shown, the printed circuit board 110 may include a semiconductor device other than the semiconductor devices 130, 130a, 130b, 130c, 130d, 130e, 130f and 130g.

In this instance, the semiconductor device is a component that is electrically connected with the printed circuit board 110 to thereby perform a predetermined function, and may denote a device that can be built in the printed circuit board 110 such as an integrated circuit (IC) chip. In addition, although not shown, it is obvious that the semiconductor device is built in the printed circuit board 110, and electrical connection for operation is performed through a via, or the like.

In addition, the main interposer 120 may include a circuit layer having a circuit pattern formed on an inner layer thereof.

In addition, the semiconductor device 130 may be formed on the main interposer 120.

In this instance, a plurality of semiconductor devices 130 may be provided.

The semiconductor device 130 according to an embodiment of the present invention may be mounted on the printed circuit board such as an integrated circuit (IC) semiconductor device, an integrated passive device (IPD), a diode, or the like, and the invention is not limited thereto.

The support interposer 140 may be disposed on the same plane as a plane of the semiconductor device 130, or disposed between the main interposer 120 and the semiconductor device 130.

In this instance, the support interposer 140 is disposed on the same plane as that of the semiconductor device 130 may denote that, as shown in FIG. 1, the support interposer 140 is disposed on the same layer as that of the semiconductor device 130.

In addition, when disposed on the same plane as that of the semiconductor device 130, the support interposer 140 may have a height corresponding to a height of the semiconductor 130 based on a thickness direction of the printed circuit board while considering stability in stacking.

Here, the word “corresponding” may denote enabling to have the same thickness as that of the semiconductor device 130. However, the word “the same” may not denote a thickness of exactly the same dimension in the mathematical sense, and denote substantially the same while taking design errors, manufacture errors, measurement errors, and the like into consideration.

In addition, the support interposer 140 may include a circuit layer having a circuit pattern formed on an inner layer thereof.

More specifically, the support interposer 140 may have a configuration which is applied for stability in stacking between the plurality of semiconductor devices 130, and may be applied to the periphery of the semiconductor device 130 above the main interposer 120 in a support manner, and therefore the stability in stacking may be ensured even when a size of the upper semiconductor device 130d is greater than that of the lower semiconductor device 130e.

In addition, each of the main interposer 120, the semiconductor device 130, and the support interposer 140 may include a through-via 150 formed based on a thickness direction of the printed circuit board.

In addition, a via hole for the through-via 150 may be processed through a method of using a laser drill such as a YAG laser or a CO2 laser in accordance with an object to be applied (the main interposer 120, the semiconductor device 130, the support interposer 140, and the like), or a method of using a machine drill such as a CNC drill.

In addition, an external connection terminal 180 is formed between the printed circuit board 110 and the main interposer 120, and connected with the through-via 150 to thereby be mutually electrically connected.

In addition, an external connection terminal 160 is formed between the plurality of semiconductor devices 130, and connected with the through-via 150 to thereby be mutually electrically connected.

In addition, the external connection terminal 160 is formed between the semiconductor device 130 and the support interposer 140, and connected with the through-via 150 to thereby be mutually electrically connected.

In addition, an external connection terminal 170 is formed between the support interposer 140 and the main interposer 120, and connected with the through-via 150 to thereby be mutually electrically connected.

That is, the external connection terminals 160, 170, and 180 are formed between the configurations to thereby be electrically connected to each other.

### 3D Semiconductor Package

### Second Embodiment

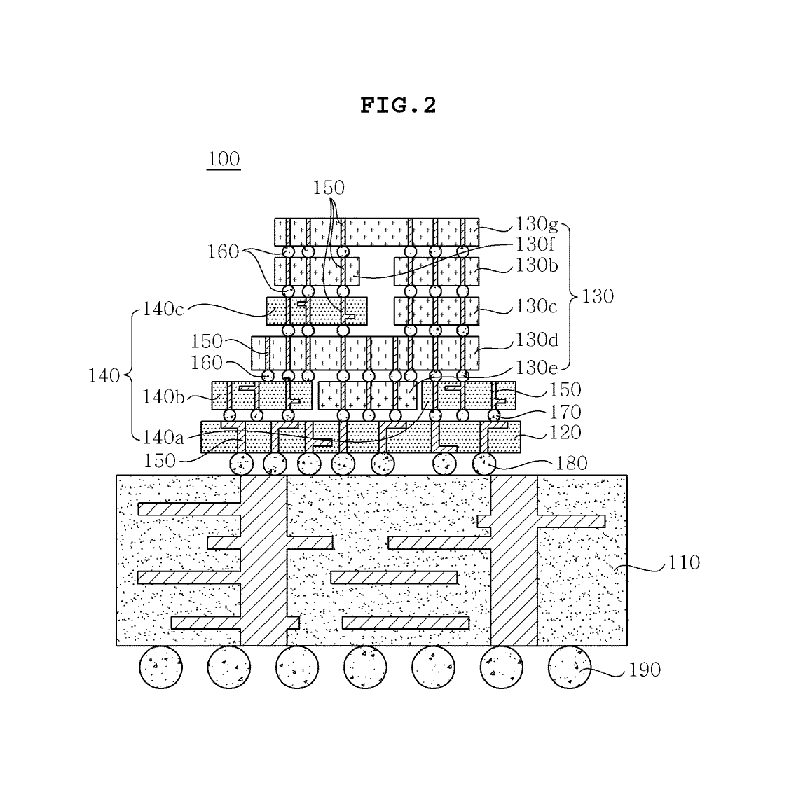

FIG. 2 is a cross-sectional view showing a configuration of a 3D semiconductor package according to another embodiment of the present invention, in detail, and a case when the support interposer is formed between the semiconductor devices will be described.

However, the same configuration as that of the first embodiment of the present invention among configurations of the second embodiment will be omitted, and only differences therebetween will be described.

As shown in FIG. 2, the 3D semiconductor package 100 may include a plurality of semiconductor devices 130, 130b, 130c, 130d, 130e, 130f, and 130g (hereinafter, the reference numerals will be referred to as “130”), and support interposers 140, 140a, 140b, and 140c (hereinafter, the reference numerals will be referred to as “140”) that are disposed on the same plane as that of the semiconductor device 130 or disposed between a plurality of semiconductor devices 130.

In this instance, the support interposer 140 is disposed between the plurality of semiconductor devices 130 may denote that, as shown in FIG. 2, the support interposer 140 is stacked between vertically stacked semiconductor devices 130f and 130d.

In addition, each of the semiconductor devices 130 and the support interposer 140 may include a through-via 150 formed based on a thickness direction of the printed circuit board.

Meanwhile, the 3D semiconductor package 100 may further include an external connection terminal 160 that is disposed between the plurality of semiconductor devices 130, and connected with the through-via 150 to thereby be mutually electrically connected.

In addition, the external connection terminals 160 may be formed between the semiconductor device 130 and the support interposer 140, and connected with the through-via 150 to thereby be electrically mutually connected.

In addition, the 3D semiconductor package 100 may further include a main interposer 120 that is formed below the plurality of semiconductor devices 130, and a printed circuit board 110 that is formed below the main interposer 120.

In this instance, the printed circuit board 110 may be a typical insulation layer applied as a core substrate in the printed circuit board fields, or a printed circuit board in which a circuit of one layer or more is formed on the insulation layer.

As the insulation layer, a resin insulation layer may be used. As the resin insulation layer, thermosetting resin such as epoxy resin, thermoplastic resin such as polyimide, or resin in which the above-described resins are impregnated with a reinforcement such as a glass fabric or an inorganic filler, for example, a prepreg may be used, or thermosetting resin or/and photocurable resin may be used, but the invention is not particularly limited thereto.

In addition, as shown in FIG. 2, the printed circuit board 110 may include an external connection terminal 190 in a lower portion thereof.

In addition, although not shown, the printed circuit board 110 may include a semiconductor device other than the semiconductor devices 130, 130a, 130b, 130c, 130d, 130e, 130f, and 130g.

In this instance, the semiconductor device is a component that is electrically connected with the printed circuit board 110 to thereby perform a predetermined function, and may denote a device that can be built in the printed circuit board 110 such as an integrated circuit (IC) chip. In addition, although not shown, it is obvious that the semiconductor device is built in the printed circuit board 110, and electrical connection for operation is performed through a via, or the like.

In addition, the main interposer 120 may further include a thorough-via 150 that is formed based on a thickness direction of the printed circuit board.

In a general semiconductor package, the semiconductor devices should be stacked in the form in which a size of the semiconductor device is reduced as closer to the upper portion for stability in stacking of the semiconductor package, and therefore there is a limitation in the degree of freedom in design of the semiconductor package.

When the semiconductor devices are stacked in such a manner that the size of the upper semiconductor device is greater than the size of the lower semiconductor device, a non-uniformity state is wholly exhibited, and therefore, reliability of the product may be weaken, and there may be a limitation in electrical signal connection.

Therefore, in the 3D semiconductor package according to the second embodiment of the present invention, the support interposer may be applied when stacking the semiconductor devices, and therefore the semiconductor device may be freely disposed in accordance with the operator's needs regardless of the size of the semiconductor device. In addition, electrical connection between respective configurations may be performed through the through-via, and therefore the overall size of the 3D semiconductor package may be reduced to be miniaturized.

As described above, in the 3D semiconductor package according to the embodiments of the present invention, the support interposer may be applied when stacking the 3D semiconductor package including the semiconductor device, and therefore stability between the semiconductor devices may be ensured even though the semiconductor devices with a variety of sizes are applied, thereby improving reliability of the product.

In addition, according to the embodiments of the present invention, the support interposer may be applied, and therefore a process of separately manufacturing a semiconductor device with a specified size other than the semiconductor device with a standardized size for stability in stacking may be omitted, thereby reducing costs and improving productivity of the products.

In addition, according to the embodiments of the present invention, it is possible to overcome the structure vulnerability and limitations in signal connection implementation when the semiconductor devices with different sizes are stacked.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations, or equivalent arrangements should be considered to be within the scope of the invention, and the detailed scope of the invention will be disclosed by the accompanying claims.

What is claimed is:

1. A three-dimensional (3D) semiconductor package comprising:
a printed circuit board;
a main interposer that is formed on the printed circuit board;
a semiconductor device that is formed on the main interposer; and
a support interposer that is disposed on the same plane as a plane of the semiconductor device, or disposed between the main interposer and the semiconductor device,
wherein each of the main interposer, the semiconductor device, and the support interposer includes a through-via formed based on a thickness direction of the printed circuit board.

2. The 3D semiconductor package as set forth in claim 1, further comprising:
an external connection terminal that is formed between the main interposer and the printed circuit board, and connected with the through-via to thereby be mutually electrically connected.

3. The 3D semiconductor package as set forth in claim 1, wherein a plurality of semiconductor devices are provided, and the 3D semiconductor package further comprises an external connection terminal that is formed between the plurality of semiconductor devices and connected with the through-via to thereby be mutually electrically connected.

4. The 3D semiconductor package as set forth in claim 1, further comprising:
an external connection terminal that is formed between the semiconductor device and the support interposer, and connected with the through-via to thereby be mutually electrically connected.

5. The 3D semiconductor package as set forth in claim 1, wherein the support interposer includes a circuit layer having a circuit pattern formed on an inner layer thereof.

6. The 3D semiconductor package as set forth in claim 1, wherein the main interposer includes a circuit layer having a circuit pattern formed on an inner layer thereof.

7. The 3D semiconductor package as set forth in claim 1, wherein the printed circuit board includes the semiconductor device built therein.

8. A 3D semiconductor package comprising:
a plurality of semiconductor devices; and
a support interposer that is disposed on the same plane as a plane of the semiconductor device, or disposed between the plurality of semiconductor devices,
wherein each of the semiconductor devices and the support interposer includes a through-via formed based on a thickness direction of the printed circuit board.

9. The 3D semiconductor package as set forth in claim 8, further comprising:
an external connection terminal that is formed between the plurality of semiconductor devices, and connected with the through-via to thereby be mutually electrically connected.

10. The 3D semiconductor package as set forth in claim 8, further comprising:
an external connection terminal that is formed between the semiconductor devices and the support interposers, and connected with the through-via to thereby be mutually electrically connected.

11. The 3D semiconductor package as set forth in claim 8, further comprising:
a main interposer that is formed below the plurality of semiconductor devices; and
a printed circuit board that is formed below the main interposer.

12. The 3D semiconductor package as set forth in claim 11, wherein the main interposer further includes a through-via that is formed based on a thickness direction of the printed circuit board.

13. The 3D semiconductor package as set forth in claim 11, wherein the printed circuit board includes a semiconductor device built therein.
